(19) United States
(12) Patent Application Publication
(10) Pub. No.: US 2008/0115029 A1
(43) Pub. Date: May 15, 2008

(54) ITERATIVE TEST GENERATION AND DIAGNOSTIC METHOD BASED ON MODELED AND UNMODELED FAULTS

(75) Inventors: Mary P. Kusko, Hopewell Junction, NY (US); Thomas J. Fleischman, Poughkeepsie, NY (US); Franco Motika, Hopewell Junction, NY (US); Phong T. Tran, Highland, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/552,567

(22) Filed: Oct. 25, 2006

(51) Int. Cl. G01R 31/28; G06F 11/00

(52) U.S. Cl. 714/742

(57) ABSTRACT

A diagnostic and characterization tool applicable to structural VLSI designs to address problems associated with fault tester interactive pattern generation and ways of effectively reducing diagnostic test time while achieving greater fail resolution. Empirical fail data drives the creation of adaptive test patterns which localize the fail to a precise location. This process iterates until the necessary localization is achieved. Both fail signatures and associated callouts as well as fail signatures and adaptive patterns are stored in a library to speed diagnostic resolution. The parallel tester application and adaptive test generation provide an efficient use of resources while reducing overall test and diagnostic time.

### FIELD OF THE INVENTION

The present invention relates to the field of Design Automation of Very Large Scale Integrated (VLSI) circuits, and more particularly, to a method of testing and subsequent diagnosing failures based on a broad range of modeled and unmodeled faults.

### BACKGROUND OF THE INVENTION

A problem often encountered when testing and subsequently diagnosing VLSI devices is the availability of effective test patterns and a precise diagnostic methodology to pinpoint the root cause of a broad range of modeled and unmodeled faults. The rapid integration growth of VLSI devices with their associated high circuit performance and complex semiconductor processes has intensified old and introduced new types of defects. This defect diversity, accompanied by the limited number of fault models, usually results in large and insufficient pattern sets with ineffective diagnostic resolution.

Identifying faults and pinpointing the root cause of the problem in a large logic structure requires high resolution diagnostic calls to isolate the defects and to successfully complete a Physical Failure Analysis (PFA) to locate those defects. The resolution of state-of-art logic diagnostic algorithms and techniques depend on the number of tests and the amount of passing and failing test result data available for each fault.

Test Pattern Generation

Test patterns are needed in manufacturing test to detect defects. Tests can be generated using a variety of methods. A representative model of the defect is typically employed and referred to as a fault model. The fault models are advantageously used to guide the generation and measure the final pattern effectiveness. The stuck-at fault model is the most commonly used model, but other models have been successfully used in industry. For a stuck-at fault model, faults are assigned to the input and outputs of each primitive block for both stuck-at-0 (S-a-0) and stuck-at-1 (S-a-1) conditions. Examples of primitive blocks, i.e., the lowest logical level in any design include AND, OR, NAND, NOR, INV gates, and the like. For each fault, a generator determines the conditions necessary to activate the fault in the logic, allowing the conditions to propagate the fault to an observation point). Tests are generated for each fault in the total set of chip faults and methods are then used to compress these patterns to maximize the number of faults tested per pattern.

In a manufacturing environment, tester time and tester memory are of prime importance; therefore, steps are taken to ensure that the patterns are as efficient as possible by testing the maximum number of faults per pattern (although more difficult to diagnose).

At final test, patterns are applied to the device under test (hereinafter referred to as DUT) and test results data is collected. Test results data typically contains both passing and failing patterns and the specific latches or pins (“observation points”) that failed and how they failed. To determine which fault explains the fail, the fail data is typically loaded into a diagnostic simulator. Each fault is analyzed to see if it explains the fail or set of fails. Resulting from this simulation is a call-out report that lists each of the suspect faults and a confidence level at which the fault can explain the fail. Callouts can range from precise calls of 100% (an exact match) to lesser confident numbers. Physical failure analysis (PFA) requires locating the failure at the precise location, and as such, a highly accurate call-out is needed. Oftentimes, the resultant diagnostic callout does not give a sufficiently clear indication of the fault location. In situations where several faults are identified but none have a precise callout, a finer resolution is needed. A focused set of patterns can be created based on a subset of faults called out during diagnostic simulation. In a typical fault simulation, the fault is marked as detected once this process has been completed.

A technique extensively used in industry is known as N-detect where a fault is detected N times, each time using a different set of activation and propagation conditions.

This methodology will now be explained in more detail. First, the set of stimuli points (latch or primary input PI) that feeds into the fault is determined. Next, a test is generated for a given fault in the absence of constraints. The first pattern serves as the basis for the remaining N-detect patterns. One by one, each stimulus point is line-held to the opposite value of the first pattern and a new test is generated. If the fault is detected, the pattern is saved as one of the N-detect patterns. The process is then repeated for each of the stimuli points to obtain the desired set of N-detect patterns.

Fault Model Models Defects

Physical defects can manifest themselves in many ways and often enough do not match any fault model. By expanding the breadth of the set of tests, the likelihood of being able to also detect un-modeled faults is increased. Conventional methods for generating test patterns and collecting associated test results are insufficient to achieve the desired diagnostic resolution.

Accordingly, there is a need in industry to provide an interactive and iterative test generation and diagnostic methodology based on specific device responses resulting in high diagnostic resolution calls.

Diagnostic Simulation

Referring to FIG. 1, a flow chart is shown illustrating a conventional methodology typically used in industry, applicable to final test of a VLSI die or multi-chip module, and which is used for determining the root cause of failure(s) and, ultimately, steps for fixing the problem causing the failure.

The chip or module to be tested is described in the form of logic model(s) (block 11) describing the DUT. Examples of such logic models can take the form of a high level representation of the logic such as behaviorals or, at the other end of the spectrum, as a netlist comprising primitives (NOR, NANDs, and the like) and their respective interconnects.

A set of test patterns also known as test vectors, is generated using one of several ATPGs (Automatic Test Patterns Generators) (block 12) which, depending on the size and complexity of the logic, may include one or more deterministic pattern generators, weighted adaptive random pattern generators, and the like. The set of patterns thus generated (block 13) is then applied to a tester (block 14) at final test.

Block 15 depicts a decision block for determining at the completion of the test (i.e., after applying all the test patterns known a priori to detect the presence of any failures), whether the chip or module passes or fails the test. Assuming that the answer is ‘yes’, the DUT is scribed, diced and mounted onto the next level of packaging. Alternatively, if the device under test fails during testing, the corresponding failing data (block 17) is handed to a set of diagnostic simulation programs (block 16) designed to localize the failure. The intent of the diagnostic tool (block 16) is to determine the fault or set of faults (block 18) which explain the fail data (block 17). The outcome of the diagnostic tool is a fault callout. Typically associated with a fault callout is a measure of how well each fault in the callout explains the occurrence of the physical failure. This performance measure provides a confidence level. The fault callout is then preferably inputted to a physical failure analysis program (block 19), wherein the correlation between logic failures is coupled to actual physical failures. Locating the physical failures makes it possible to determine the root cause of the problem (block 191) allowing the engineer to take the necessary steps to fix the problem (block 192).

A significant problem pertaining final test that also includes test pattern generation (TPG) and simulation, relates to the large volumes of patterns that are necessary to test the DUT and the test time allocated to each chip in a wafer. This problem has manifested itself to such a degree that final test has become over the years a major component of the cost of manufacturing VLSI products. In view of the ever increasing circuit density in chips which has been a major contributor to the speed and performance of IC, test time is fast becoming unmanageable. The problem is compounded in that conventional techniques are inadequate for handling the test problem effectively.

As a result, there is a need in industry for a workable solution that makes it possible to reuse subsets of the test patterns used in a previous failing final test chip, and which adequately identifies specific faults, to be stored, and subsequently retrieved for testing similar chips suspected to contain the same failures.

### OBJECTS AND SUMMARY OF THE INVENTION

Accordingly, it is a primary object of the invention to provide a diagnostic and characterization tool applicable to structural VLSI designs to reduce the volume of test patterns when addressing problems associated with fault tester interactive pattern generation.

It is another object to increase the accuracy of fault callouts and subsequent physical failure analysis.

It is still another object to enable enhanced diagnostic resolution in a more timely and cost efficient manner.

It is still another object to provide a method for empirically adapting test experience gained by testing and diagnosing other similar DUTs and applying the same test patterns to other DUTs known to have the same faults, in order to enhance and expedite diagnostic fault resolution.

These and other objects, advantages and aspects of the invention are achieved by providing a method for diagnosing and pinpointing root causes of modeled and unmodeled faults in a DUT that includes the steps of:

testing said DUT by applying a set of test patterns and storing a signature when the test fails, said signature being indicative and representative of a failure in said DUT;

executing a diagnostic simulation to obtain fault callouts, and correlating the signature indicative of the failure by comparing it to stored signatures; and

applying to said DUT the set of test patterns associated with said signature.

The method of the present invention achieves high confidence fault detection tests which are identified by using standard diagnostic techniques and generating N-detect set of patterns for modeled faults associated with the identified nets. The tests are than re-applied using these focused patterns and corresponding failing passing responses logged and utilized for intermediate diagnostic analysis. The above process is then repeated until a desired diagnostic confidence level is achieved. The high diagnostic resolution solution is preferably provided via an interactive and iterative test generation and diagnostic methodology that is based on specific device responses.

The method of the present invention enables an awareness of otherwise undetectable repetitive conditions. Thus, adaptive test pattern generation (also referred to Testgen or TPG) can proceed in parallel with the test application, improving the tester time while the fault resolution increases significantly. (Note: other methods besides N-detect can be used for TPG).

### BRIEF DESCRIPTION OF THE DRAWINGS

The accompanying drawings, which are incorporated in and which constitute part of the specification, illustrate the presently preferred embodiments of the invention which, together with the general description given above and the detailed description of the preferred embodiments given below serve to explain the principles of the invention.

FIG. 1 is a diagram showing a prior art basic flow typically used for diagnostic simulation to pinpoint and localize faults while testing a DUT.

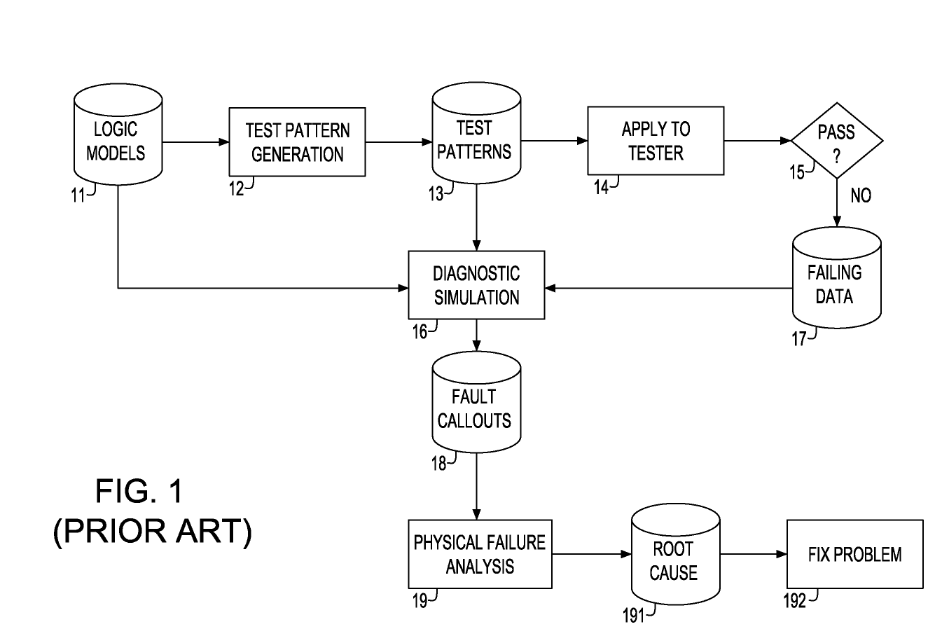

FIG. 2 is a flow chart showing steps describing the Iterative N-Detect Method using a library that includes fault signatures, callouts and patterns empirically learned, according to a preferred embodiment of the invention.

FIG. 3 is a flow chart showing steps describing the Iterative N-Detect Method making use of a library that includes the signatures, fault callouts and patterns after diagnostic simulation and generation of adaptive patterns, according to the preferred embodiment of the invention.

FIG. 4 is flow chart showing steps describing the Iterative N-Detect Method showing adaptive parallel tester application and adaptive test pattern generation, making use of a library that contains a reduced set of adaptive test patterns leading to a predetermined signature for a given failing die, according to the preferred embodiment of the invention.

FIG. 5 is a flow chart showing steps describing the Iterative N-Detect Method illustrating parallel tester application and adaptive test generation using a library that includes a) signatures, b) fault callouts, c) adaptive patterns, and d) die identification, according to the preferred embodiment of the invention.

FIG. 6 shows a graphic representation of the iterative localization process for an initial test stimulus (FIG. 6A) followed by a first pass test pattern stimulus (FIG. 6B).

FIG. 7 shows the same graphical representation of the iterative localization process repeating itself until a desired diagnostic confidence is achieved (FIG. 7A), followed by identifying the localized fault (FIG. 7B).

### DETAILED DESCRIPTION

A preferred embodiment of the present invention is described hereinafter illustrating several system components that tightly and interactively couple the test pattern generation and tester execution process.

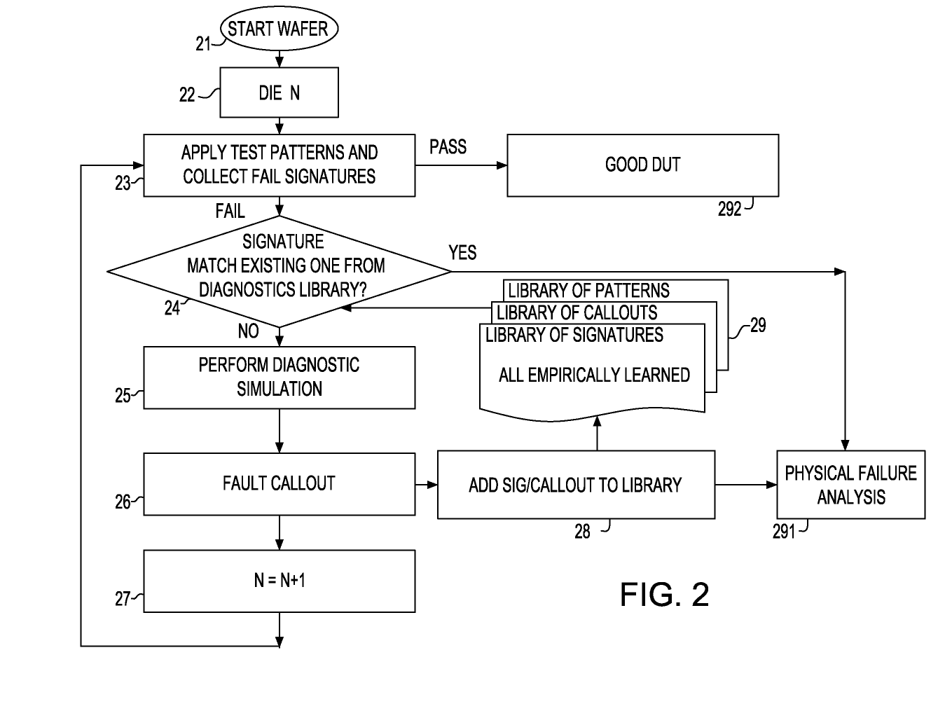

Referring to FIGS. 2-5, the flow and functional components of the Iterative Diagnostic Process are illustrated. The test generation, fault simulation and diagnostic simulation blocks have inputs from the logic design and fault models. The test generation block provides manufacturing test patterns and custom interactive diagnostic patterns, labeled N-detect patterns in the respective figures. Other special purpose algorithms are also invoked to generate custom patterns, as will be described hereinafter.

The iterative diagnostic and test execution process invokes an Adaptive Fail Device Specific Iterative Process multiple times until a desired diagnostic resolution is achieved.

The process steps preferably include:
1. Identifying the highest confidence nets using standard diagnostic techniques;
2. Generating N-detect patterns (e.g., times 20) for the modeled faults associated with selected nets (e.g., the top 5% calls);
3. Retesting by using focused patterns;
4. Rerunning the diagnostics; and
5. Repeating the above steps until a desired confidence factor is achieved.

Additionally, the Physical Design Model and diagnostic calls data, i.e., the failing nets are subsequently inputted to Physical Failure Analysis (PFA) at the end of the diagnostic test to determine the root cause of the problem.

Referring now to FIG. 2, there is shown a flow chart detailing the steps of the present methodology making use of a library containing empirically learned fail signatures and fault callouts to expedite the diagnostics process. When a test pattern is applied to the DUT (23), if the measured response matches the expected response, then the pattern passes (292). If the measured responses do not match the expected response, they are indicative of a fail condition. The measurements (i.e., observed values at the primary outputs of the die) of the failing patterns create a fail signature (23). Thus, the failing measures forming the fail signature are attributed to a defect or problem causing the fail to occur.

When a device fails, the library is referenced (29) to determine whether a callout has already been encountered for the particular fail signature (24). If a callout already exists, then diagnostics follows, ultimately leading to a Physical Failure Analysis (PFA) (291) using the predetermined callout location. If a signature does not exist (24), then the process continues by executing the diagnostics simulation (25) where a fault callout (26) is determined. With the fault callout determined, the signature and callout are added to the library and the device is ready for PFA. This process repeats itself by testing each chip on the wafer until sufficient fail information has been collected or until all the chips on the wafer are tested.

A library of empirical signatures does not initially exist. Instead it must be built from the devices being tested. As soon as the first DUT fails and a fault callout (26) are identified by the diagnostic simulation (25), the callout and corresponding fail signature are added to the library (28 and 29). Upon subsequent testing, as more devices fail, fault callouts (26) are determined from the diagnostic simulation (25) and are added to the library (28 and 29), thereby building a library containing the fail signatures and fault callouts.

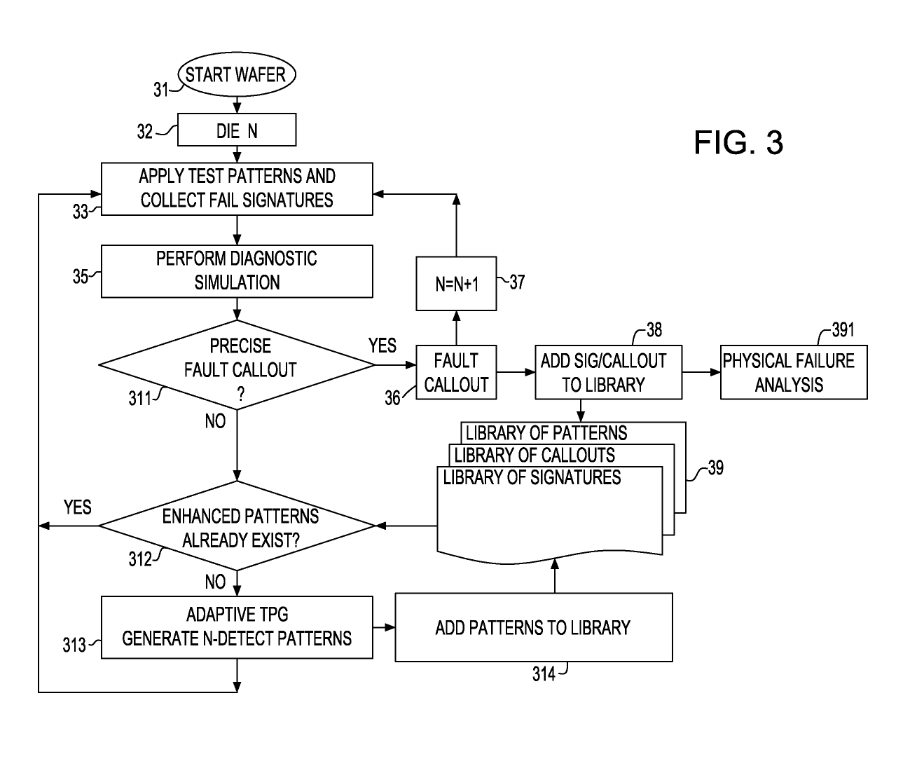

Referring now to FIG. 3, the method of the preferred embodiment of the invention using an ‘upgraded’ library is described. This time, the library houses an enhanced set of patterns which enables diagnostic resolution on more difficult to diagnose fails. Test patterns are applied (33) and diagnostic simulation is executed for the failing response (35). Resulting from the simulation is a fault callout and corresponding score. If the score is indicative of a lack of high confidence (311), then other methods must be employed to increase the accuracy of the callout. One such method is to create or use a focused set of patterns. First, the library (39) is searched to determine whether enhanced patterns already exist (312). If such patterns exist, then they are applied to the DUT (33). If they do not exist, then an iterative fault localization process is preferably used to create focused patterns to narrow down and hone in on the fault callout that explains the fail (313). Once the new patterns have been generated, they are added to the library (314) and applied to the DUT (33). This process is replicated until an accurate callout is achieved (311, 36). This new signature and callout are added to the library (39) before proceeding to PFA (391).

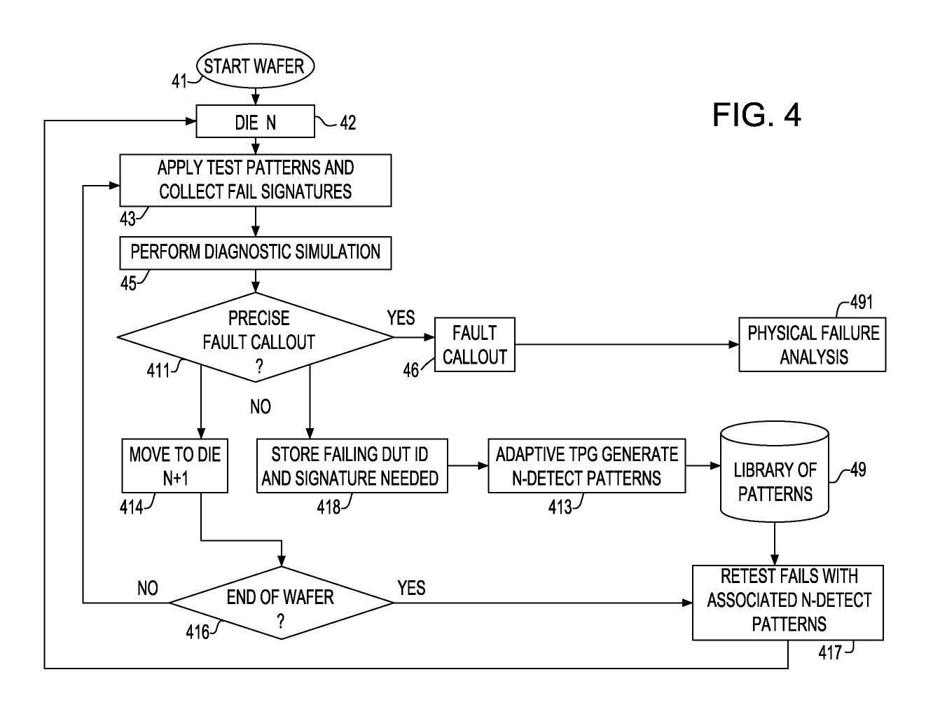

Referring now to FIG. 4, a method describing parallel tester application and diagnostic test generation is illustrated. Test patterns are applied and fail signatures collected (43) as previously described. Diagnostic simulation is performed to determine the root cause of the fail (45). If an accurate callout (411, 46) results from the simulation then the device is ready for PFA (491). Otherwise, an iterative fault localization process is advantageously invoked to generate a focused set of patterns (413) while concurrently the tester proceeds to testing the next device (414). Failing DUT identification and associated signature are stored for use at retest time (418). The process is repeated (43) until the entire wafer has been tested (416) at which time the tester returns to the previous failing DUTs in need for further fault localization. Associated patterns are used for each failing DUT.

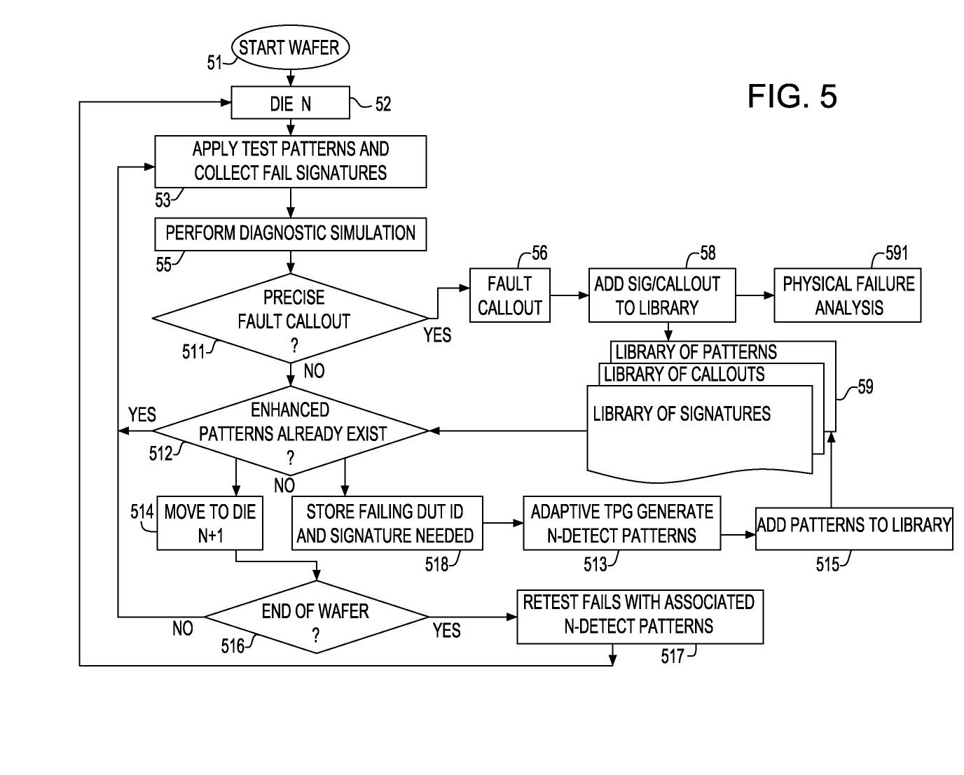

Referring now to FIG. 5, there is shown a method that combines the use of the library incorporating the foregoing parallel tester application and diagnostic test generation. Test patterns are applied (53) and diagnostic simulation is executed on the failing response (55). Resulting from the simulation is a fault callout(s) and associated score(s). If the score lacks the required high level of confidence (511), then other methods are preferably employed to increase the accuracy of the fault callout. One such method is to create or use a focused set of patterns. First, the library (59) is searched to determine whether enhanced patterns already exist (512). If such patterns exist, then they are applied to the DUT (53). If they do not exist, an iterative fault localization process is preferably used to create focused patterns to narrow down and hone in on the fault callout that explains the fail (513). In parallel with the diagnostic test generation, the tester proceeds to testing the next device. Prior to moving to the next device, the DUT identification and fail signature are stored for use at retest time. Any new pattern generated is added to the library (514). The process is repeated (53) until the entire wafer is tested (516) at which time the entire set of failing devices are retested with the associated enhanced set of patterns.

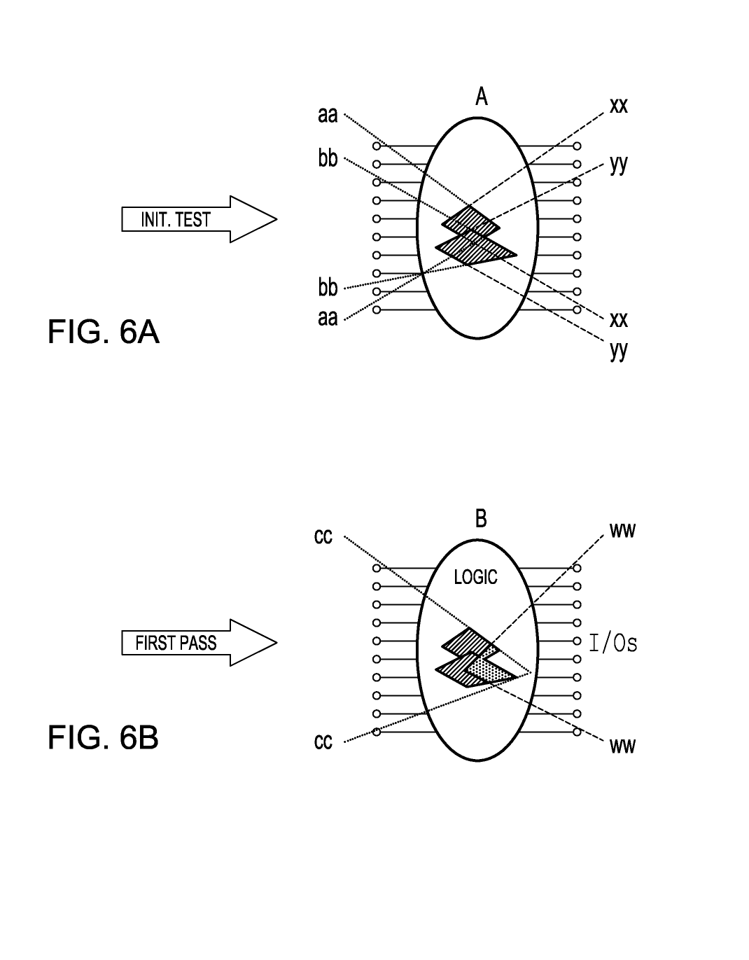

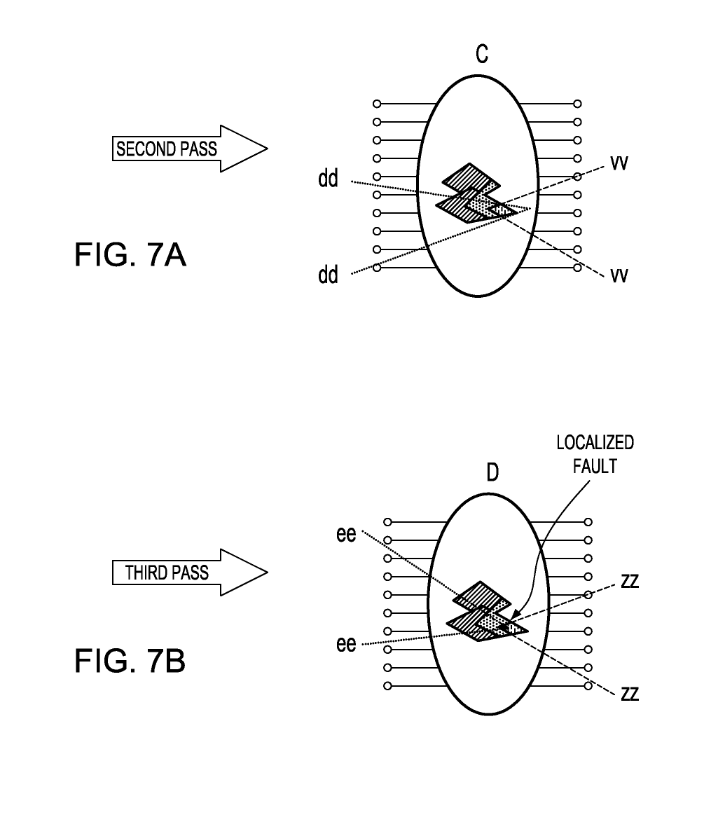

FIGS. 6 and 7 graphically depict how device failure signatures are preferably used to increase the resolution of failing nodes.

The initial test patterns are run against a device and observable nodes (outputs) that do not match the expected of a ‘good’ device (i.e., good machine) are logged alongside the fail signature. The fail outputs are traced back through the device model, expanding into a ‘cone’ of possible circuits which may be the cause of the fail seen at the primary outputs. As the signatures for each fail are traced back through the device, the cones end overlapping. The overlapping cone regions (FIG. 6A) identify the circuit areas where the fails have a high probability of being located.

In view of today's circuit complexity and high transistor count, the overlapping regions for the fail cones do not have sufficient resolution to allow for failure diagnostics and analysis. Thus, additional test patterns are needed to magnify the resolution. In order to increase the resolution of the tests, the overlapping region circuit information is passed to the test pattern generator and patterns unique for these regions are generated. The device is then retested. As shown in FIG. 6, the new failures observed generate a unique signature of their own and can be used to identify new failure cones.

Referring to FIGS. 6 and 7, the failure cone region shown in FIG. 7 needs further resolution for proper diagnostics and analysis to be performed. The steps to increase the resolution of fails are repeated in steps FIGS. 7A and 7B (and continued until a desired resolution is achieved).

The present invention is effective for unmodeled faults, AC faults, net-to-net defects, pattern sensitive faults, and the like. It has a further advantage in that it introduces full compatibility between functional and structural test methodologies. The method of the present invention is highly interactive and allows for being adapted to a convergent diagnostic pattern generation. It successfully utilizes conventional test generation and diagnostic algorithms, and can be easily integrated in current test system architectures and test flow.

Finally, the present invention can be realized in hardware, software, or a combination of hardware and software. The present invention can be realized in a centralized fashion in one computer system or in a distributed fashion where different elements are spread across several interconnected computer systems. Any kind of computer system—or other apparatus adapted for carrying out the methods described herein—is suitable. A typical combination of hardware and software could be a general purpose computer system with a computer program that, when being loaded and executed, controls the computer system such that it carries out the methods described herein.

The present invention can also be embedded in a computer program product, which comprises all the features enabling the implementation of the methods described herein, and which—when loaded in a computer system—is able to carry out these methods.

Computer program means or computer program in the present context mean any expression, in any language, code or notation, of a set of instructions intended to cause a system having an information processing capability to perform a particular function either directly or after conversion to another language, code or notation and/or reproduction in a different material form.

While the present invention has been particularly described in conjunction with exemplary embodiments, it is evident that many alternatives, modifications and variations will be apparent to those skilled in the art in light of the present description. It is therefore contemplated that the appended claims will embrace any such alternatives, modifications and variations as falling within the true scope and spirit of the present invention.

What is claimed is:

1. A method for diagnosing and pinpointing root causes of modeled and unmodeled faults in a device under test (DUT) comprising the steps of:
a) testing said DUT by applying a set of test patterns and storing a signature when the test fails, said signature being indicative of a failure in said DUT; and
b) executing a diagnostic simulation to obtain fault callouts, and correlating the signature indicative of said failure by comparing it to stored signatures; and
c) applying to said DUT the set of test patterns associated with said signature.

2. The method of claim 1, wherein steps a) through c) are iterated until said correlation is established.

3. The method of claim 1, wherein if said correlation is established or said failure is localized or a predetermined confidence level is achieved, a physical failure analysis is performed to determine a root cause of said failure.

4. The method of claim 1, wherein if said DUT fails, a library determines whether a fault callout indicative of said failure was already created for said signature, and if said callout already exists, then proceeding to Physical Failure Analysis (PFA) at the location of said fault callout.

5. The method of claim 4, wherein if said signature does not exist, then a diagnostics simulation is performed to determine the fault callout most likely to explain the failure.

6. The method of claim 4, wherein when said fault callout is determined, the fault callout and its corresponding signature are stored in said library and the DUT is readied for PFA.

7. The method of claim 1, further comprising the step of generating a set of test patterns to localize the fail and applying said set of test patterns to the DUT if no correlation is established and said fault callout fails to achieve a predetermined accuracy.

8. The method of claim 1, wherein said set of test patterns is applied to others of said DUTs in parallel while generating other sets of test patterns for localizing the failure.

9. The method of claim 1, wherein diagnosing and pinpointing said root causes applies to modeled, unmodeled faults, AC faults, net-to-net faults, pattern sensitive faults, and any combination thereof.

10. The method of claim 1, wherein said signatures, fault localizing test patterns, and corresponding root causes associated to said corresponding fault callouts are stored in a library.

11. A method for diagnosing and pinpointing root causes of modeled and unmodeled faults in a device under test (DUT) comprising the steps of:
a) identifying a highest scoring fault callout using diagnostic simulation;
b) generating a deterministic set of localizing patterns for faults associated with said identified nets and determining corresponding signatures;
c) re-applying tests using said set of deterministic patterns and
d) repeating steps a) through c) until said highest scoring fault callout is achieved.

12. The method of claim 11, wherein said patterns are N-detect patterns.

13. The method of claim 11 wherein said deterministic patterns and corresponding signatures are stored in a library.

14. The method of claim 11, wherein said predetermined level of confidence fault callout is stored with the deterministic patterns and corresponding signatures in a library.

15. The method of claim 11, wherein said deterministic patterns with corresponding signatures are reused in real time.

16. The method of claim 11, wherein in step c) data for intermediate diagnostic analysis is logged in.

17. The method of claim 11, wherein in step e) said signatures are catalogued in said library.

18. The method of claim 14, wherein said set of deterministic test patterns is applied to said DUTs in parallel while generating other deterministic test patterns for localizing the fail.

19. A program storage device readable by a machine, tangibly embodying a program of instructions executable by the machine to perform method steps for diagnosing and pinpointing root causes of modeled and unmodeled faults in a device under test (DUT), said method steps comprising:
testing said DUT by applying a set of test patterns and storing a signature when the test fails, said signature being indicative of a failure in said DUT;
executing a diagnostic simulation to obtain fault callouts, and correlating the signature indicative of said failure by comparing it to stored signatures;
executing a diagnostic simulation to obtain fault callouts, and correlating the signature indicative of said failure by comparing it to stored signatures; and
applying to said DUT the set of test patterns associated with said signature.
